(19) United States
(12) Patent Application Publication
(10) Pub. No.: US 2021/0249232 A1
(43) Pub. Date: Aug. 12, 2021

(54) APPARATUS AND METHOD FOR ETCHING

(71) Applicant: TAIWAN SEMICONDUCTOR MANUFACTURING COMPANY LTD., Hsinchu (TW)

(72) Inventors: HUNG-BIN LIN, NEW TAIPEI CITY (TW); LI-CHAO YIN, HSINCHU CITY (TW); SHIH-TSUNG CHEN, NEW TAIPEI CITY (TW); YU-LUNG YANG, TAICHUNG CITY (TW); YING CHIEH WANG, TAINAN CITY (TW); BING KAI HUANG, TAINAN CITY (TW); SU-YU YEH, TAINAN CITY (TW)

(21) Appl. No.: 16/786,400

(22) Filed: Feb. 10, 2020

(51) Int. Cl. H01J 37/32; H01L 21/67; H01L 21/687; H01L 21/3065

(52) U.S. Cl. CPC H01J 37/32642; H01L 21/67069; H01J 2237/3341; H01L 21/3065; H01J 37/32715; H01L 21/68735

(57) ABSTRACT

An apparatus includes a chamber, a pedestal configured to receive and support a semiconductor wafer in the chamber, and an edge ring disposed over the pedestal. The edge ring includes a first portion having a first top surface, a second portion coupled to the first portion and having a second top surface lower than the first top surface, and a recess defined in the first portion. The second top surface is under the semiconductor wafer. The recess has a depth, and a distance between the pedestal and an inner surface of the recess is substantially equal to the depth of the recess.

### BACKGROUND

Semiconductor devices are used in variety of electronic applications, such as, for example, personal computers, cellular telephones, digital cameras, and other electronic equipment. Semiconductor devices are typically fabricated by sequentially depositing material layer such as insulating or dielectric layers, conductive layers, and semiconductor layers over a semiconductor substrate, and patterning the various material layers using lithography and etching processes to form circuit component and elements thereon.

Etching processes includes wet etching, in which one or more chemical reagents (also referred to as etchants) are brought into direct contact with the substrate or layer. Another etching process is dry etching, such as plasma etching, reactive ion (RI) etching and reactive ion beam etching. In each of these etching processes, a gas is introduced into a reaction chamber and then plasma is generated from the gas. This may be accomplished by dissociation of the gas into ions, free radicals and electrons using an RF (radio frequency) generator. An electric field is generated, and the energized electrons strike gas molecules to form additional ions, free radicals and electrons, which strike more gas molecules, and the plasma thus eventually becomes self-sustaining. The ions, free radicals and electrons in the plasma react with the material to form products which leave the layer surface, and thus the material is etched from the substrate.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic drawing illustrating an apparatus for etching according to aspects of one or more embodiments of the present disclosure.

FIG. 2 is a schematic drawing illustrating an edge ring according to aspects of one or more embodiments of the present disclosure.

FIG. 3 is a schematic drawing illustrating an edge ring according to aspects of one or more embodiments of the present disclosure.

FIG. 4 is a schematic drawing illustrating an edge ring according to aspects of one or more embodiments of the present disclosure.

FIG. 5 is a schematic drawing illustrating a third portion of the edge ring according to aspects of one or more embodiments of the present disclosure.

FIG. 6A is a top view of an edge ring according to aspects of one or more embodiments of the present disclosure, FIG. 6B is a cross-sectional view taken along line I-I′ of FIG. 6A, and FIG. 6C illustrates a portion of the edge ring shown in FIG. 6A.

FIG. 7 is a flowchart representing a method for etching according to aspects of the present disclosure.

FIG. 8 is a schematic drawing illustrating a portion of an apparatus for etching during operation according to aspects of one or more embodiments of the present disclosure.

FIG. 9 is a chart illustrating electric potentials during an operation in the apparatus according to aspects of one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

A dry etching is performed in an etching chamber typically having a grounded chamber wall, an electrode positioned adjacent to a dielectric layer which separates the electrode from the interior of the chamber, a gas supply providing plasma-generating source gases, a gas removal mechanism used to remove volatile reaction products and unreacted plasma species, and an edge ring that contains a wafer being processed. In some embodiments, electric power such as a high voltage signal is applied to the electrode to ignite the plasma in the chamber. Ignition of plasma in the chamber is accomplished primarily by electrostatic coupling of the electrode with the source gases. Due to the high voltage applied to the electrode, electric fields are generated in the chamber. Once ignited, the plasma is sustained by electromagnetic induced effects which are associated with time-varying magnetic fields due to the alternating currents applied to the electrode. In some comparative embodiments, it is found that reactants used to etch the semiconductor wafer may react with a surface material or coating of the edge ring, and thus edge ring erosion may occur in a high-bias voltage process regime.

The edge ring is a key part which surrounds the wafer to provide uniform electric field and radical flow pattern. The edge ring also provides electrostatic discharge (ESD) protection. It is found that the edge ring erosion may cause adverse effect on the electric field and radical flow pattern uniformity, and thus the etching rate may be reduced. Consequently, the process performance may be unexpected and unpredictable. Further, the service life of the edge ring is reduced.

The present disclosure therefore provides an edge ring and an apparatus including the edge ring that includes an inner body with low dielectric constant (low-k) materials. In some embodiments, the inner body with the low-k material helps to reduce capacitance of the edge ring, resulting in capacitance that is proportional to the erosion rate. Accordingly, the etching rate may be maintained and the process performance may remain predictable. Further, because the erosion rate is reduced, the service life of the edge ring is increased.

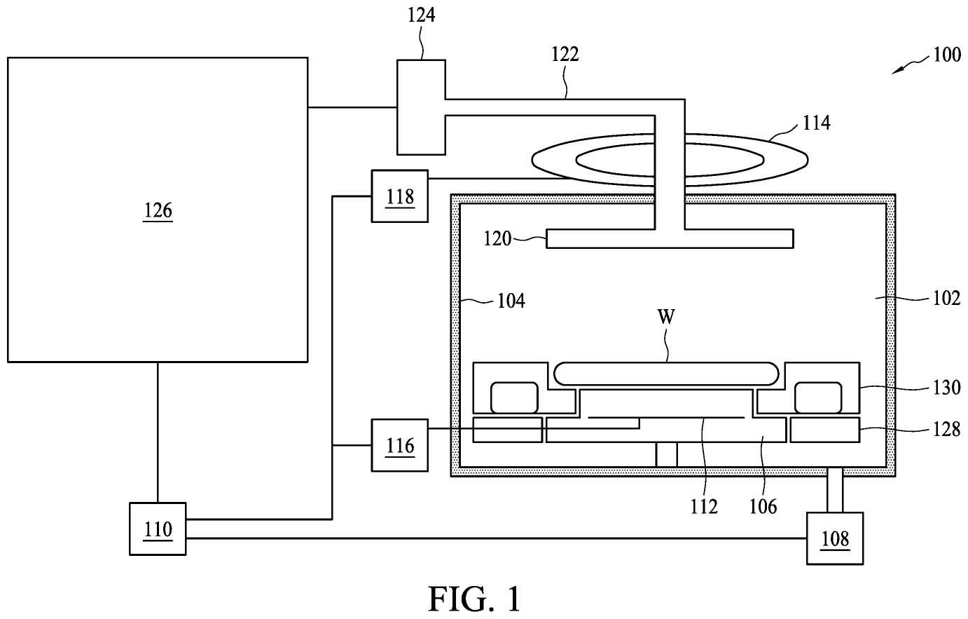

FIG. 1 is a schematic drawing illustrating an apparatus for etching according to aspects of one or more embodiments of the present disclosure. The apparatus for etching 100 includes a chamber 102. The chamber 102 may be any desired shape that is suitable for dispersing etchant such that the etchant can contact a semiconductor wafer W. As shown in FIG. 1, the chamber 102 may have a cylindrical sidewall and a bottom. However, it is not limited to a cylindrical shape, and any other suitable shape, such as a hollow square tube, an octagonal shape, or the like, may be utilized. The chamber 102 can be defined by a chamber housing 104, which includes any suitable material that can withstand the chemicals and pressures involved in the etching process. In some embodiments, the chamber housing 104 can include steel, stainless steel, nickel, aluminum, alloys of these, combinations of these, or the like.

The apparatus for etching 100 includes a pedestal 106 configured to receive and support the semiconductor wafer W in the chamber 102. The pedestal 106 may hold the semiconductor wafer W using electrostatic (ESC) forces, clamps, vacuum pressure, combinations of these, and the like. In some embodiments, the pedestal 106 may include heating and cooling mechanisms in order to control a temperature of the semiconductor wafer W during the processes.

In some embodiments, the chamber 102 can be connected to a vacuum pump 108 controlled by a controller 110. The vacuum pump 108 may be utilized to adjust a pressure within the chamber 102 to a desired pressure. In some embodiments, when the etching operation is completed, the vacuum pump 108 may be utilized to evacuate the chamber 102 in preparation for removal of the semiconductor wafer W.

The apparatus for etching 100 includes a first electrode 112 and a second electrode 114 configured to apply radio-frequency (RF) power. As shown in FIG. 1, the first electrode 112 may be a lower electrode disposed in the pedestal 106. The first electrode 112 can be coupled to a lower RF generator 116, electrically biased by the lower RF generator 116, and is controlled by the controller 110 at an RF voltage during the etching operation. Accordingly, the first electrode 112 provides a bias to the incoming etchants and assists in igniting them into a plasma. In some embodiments, the first electrode 112 also helps to maintain the plasma during the etching process by maintaining the bias and helps to accelerate ions from the plasma towards the semiconductor wafer W. The second electrode 114 may be an upper electrode coupled to an upper RF generator 118, for use as a plasma generator. In some embodiments, the plasma generator may be a transformer-coupled plasma generator and may be, for example, a coil. The upper RF generator 118 provides power to the second electrode 114 controlled by the controller 110 in order to ignite the plasma during introduction of the reactive etchants.

Although the second electrode 114 is described above as a transformer-coupled plasma generator, embodiments are not intended to be limited to a transformer-coupled plasma generator. Rather, any suitable method of generating the plasma, such as inductively-coupled plasma systems, magnetically-enhanced reactive ion etching, electron cyclotron resonance, a remote plasma generator, or the like, may be utilized. All such methods are fully intended to be included within the scope of the embodiments.

The apparatus for etching 100 includes a showerhead 120, a manifold 122, an etchant controller 124 and an etchant delivery system 126 that may cooperate to deliver one or more gaseous etchants to the chamber 102. In some embodiments, the etchant delivery system 126 supplies the various desired etchants to the chamber 102 through an etchant controller 124 and a manifold 122. The etchant delivery system 126 may also help to control the flow rate of the etchant or etchants into the chamber 102 by controlling the flow and pressure of a carrier gas through the etchant delivery system. The etchant delivery system 126 and the chamber 102 may be controlled by the controller 110, which controls and regulates the introduction of various etchants and carrier gases to the chamber 102.

Although not shown, the etchant delivery system 126 may include a plurality of etchant suppliers. It should be appreciated that any suitable number of etchant suppliers may be included, such as one etchant supplier for each etchant desired to be used within the apparatus for etching 100. For example, in some embodiments, five separate etchants may be utilized, along with five or more of the etchant suppliers. Although not shown, each of the etchant suppliers may be a vessel, such as a gas storage tank, that is located either proximal to the chamber 102 or remote from the chamber 102. In other embodiments, the etchant suppliers may be part of a facility that independently prepares and delivers the desired etchants. Any suitable source for the desired etchants may be utilized as the etchant suppliers, and all such sources are fully intended to be included within the scope of the embodiments.

Although not shown, the etchant delivery system 126 may include a carrier gas supply. The carrier gas supply may supply a desired carrier gas, or diluent gas, that may be used to help push or “carry” the various desired etchants to the chamber 102. The carrier gas may be an inert gas or other gas that does not react with the etchant itself or with by-products from the etchant's reactions. For example, the carrier gas may be nitrogen (N₂), helium (He), argon (Ar), combinations of these, or the like, although other suitable carrier gases may be utilized. The carrier gas supply, or diluent supply, may be a vessel, such as a gas storage tank, that is located either locally to the chamber 102 or remotely from the chamber 102. Any suitable source for the carrier gas may be utilized as the carrier gas supply, and all such sources are fully intended to be included within the scope of the embodiments. In some embodiments, the etchants and the carrier gases are introduced into the chamber 102 through the etchant controller 124, which controls an entry into the chamber, the manifold 122 and the showerhead 120.

As shown in FIG. 1, the showerhead 120 is disposed in the chamber 102. In some embodiments, the showerhead 120 receives the various etchants from a manifold 122 and helps to disperse the various etchants into the chamber 102. The showerhead 120 may be designed to evenly disperse the etchants in order to minimize undesired process conditions that may arise from uneven dispersal. In an embodiment, the showerhead 120 may have a circular design with openings dispersed evenly around the showerhead 120 to allow for the dispersal of the desired etchants into the chamber 102. However, any suitable method of introducing the desired etchants, such as use of entry ports, may be utilized to introduce the desired etchants into the chamber 102.

Still referring to FIG. 1, in some embodiments, the apparatus for etching 100 further includes at least a ring assembly 128 disposed in the chamber 102 and an edge ring 130 disposed over the ring assembly 128 and the pedestal 106. In some embodiments, the ring assembly 128 has an annular configuration. Further, the ring assembly 128 is disposed around the pedestal 106 and configured receive the edge ring 130. The edge ring 130 is an annular, replaceable component that surrounds the semiconductor wafer W to provide a uniform electric field and radical flow pattern. The edge ring 130 also provides electrostatic discharge (ESD) protection.

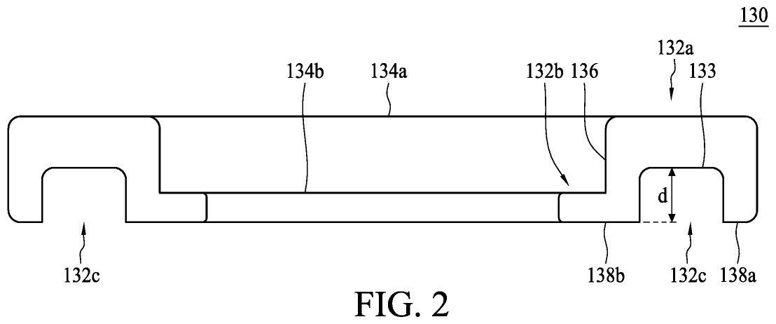

Referring to FIGS. 1 and 2, FIG. 2 is a cross-sectional view of an edge ring 130 according to aspects of one or more embodiments of the present disclosure. In some embodiments, the edge ring 130 includes a first portion 132a and a second portion 132b coupled to the first portion 132a. The first portion 132a has a ring configuration, and the second portion has a ring configuration, respectively. In some embodiments, a thickness of the first portion 132a is greater than a thickness of the second portion 132b. In some embodiments, a width of the first portion 132a is greater than a width of the second portion 132b. The first portion 132a has a first top surface 134a, the second portion 132b has a second top surface 134b, and the second top surface 134b is lower than the first top surface 134a. Because the first portion 132a has the ring configuration, the first top surface 134a is a ring-shaped top surface. Similarly, because the second portion 132b has the ring configuration, the second top surface 134b is a ring-shaped top surface. As shown in FIG. 1, in some embodiments, the first top surface 134a may be higher than a top surface of the semiconductor wafer W. In some embodiments, the second top surface 134b may be lower than a bottom surface of the semiconductor wafer W. That is, the second top surface 134b (of the second portion 132b) is under the semiconductor wafer W. In some embodiments, a surface 136 coupling the first portion 132a and the second portion 132b is perpendicular to the first top surface 134a and the second top surface 134b. In other embodiments, the surface 136 coupling the first portion 132a and the second portion 132b is a slanted surface.

In some embodiments, the first portion 132a and the second portion 132b are monolithic. In such embodiments, the first portion 132a and the second portion 132b of the edge ring 130 can be made from relatively high-conductive electrode materials such as silicon carbide and silicon or from dielectric materials such as quartz. By changing the edge ring material, the degree of coupling through the plasma can be tailored to provide a desired localized plasma density at an edge of the semiconductive wafer W being processed. For example, silicon carbide, having a lower capacitive impedance, generally produces a higher plasma density than silicon. Quartz and other dielectrics have a lesser effect on the edge plasma density. Accordingly, the first portion 132a and the second portion 132b have a dielectric constant. For example, when silicon carbide is used to form the edge ring 130, the dielectric constant of the first portion 132a and the second portion 132b is between approximately 6.5 and approximately 10. When silicon, such as intrinsic (undoped)polysilicon, is used to form the edge ring 130, the dielectric constant of the first portion 132a and the second portion 132b is approximately 11.9. When quartz, such as intrinsic (undoped) polysilicon, is used to form the edge ring 130, the dielectric constant of the first portion 132a and the second portion 132b is approximately 3.8.

In some embodiments, the edge ring 130 includes an recess 132c defined in the first portion 132a, as shown in FIG. 2. In some embodiments, a width of the recess 132c is less than a width of the first portion 132a, and a depth d of the recess 132c is less than the thickness of the first portion 132a. Accordingly, inner surfaces of the first portion 132a are exposed through the recess 132c. As shown in FIG. 2, the first portion 132a has a first bottom surface 138a opposite to the first top surface 134a, the second portion 132b has a second bottom surface 138b opposite to the second top surface 134b, and the first bottom surface 138a is aligned with and coupled to the second bottom surface 138b. As shown in FIG. 1, in some embodiments, a distance between the pedestal 106 (or the ring assembly 128) and an inner surface 133 parallel to the first top surface 134a of the first potion 132a is substantially equal to the depth d of the recess 132c.

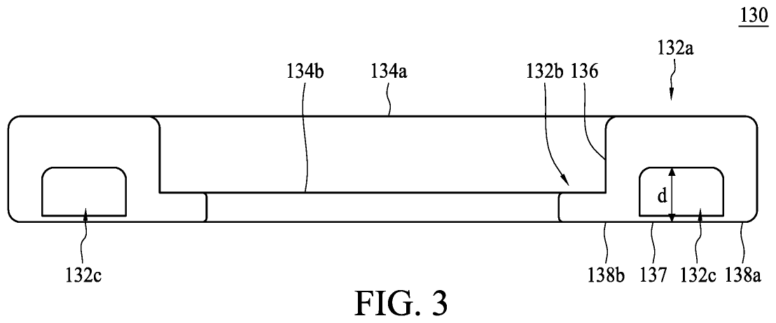

FIG. 3 is an enlarged view of the edge ring 130 according to aspects of one or more embodiments of the present disclosure. In some embodiments, the edge ring 130 further includes a seal member 137. Further, the seal member 137 seals the recess. As a result, a third portion 132c, such as a hollow portion, is sealed within the first portion 132a and the seal member 137. In such embodiments, the first bottom surface 138a of the first portion 132a, the second bottom surface 138b of the second portion 132b and the seal member 137 are in contact with the ring assembly 128 or the pedestal 106. In some embodiments, at least the second bottom surface 138b is in contact with pedestal 106. In some embodiments, the third portion 132c can include air. In other embodiments, the third portion 132c can include a vacuumed pressure.

It should be noted that the third portion 132c may include a dielectric constant, wherein the dielectric constant of the third portion 132c is less than the dielectric constant of the first portion 132a and the second portion 132b. For example, in an embodiment wherein when the third portion 132c contains air at atmosphere pressure sealed by the first portion 132a and the seal member 137, at room temperature (25° C. or 77° F.), the dielectric constant of air at atmosphere pressure is approximately 1.00059. When the third portion 132c is sealed at a vacuum pressure, the dielectric constant of the third portion 132c is approximately 1, which is less than the dielectric constant when the third portion 132c is sealed with air at atmosphere pressure.

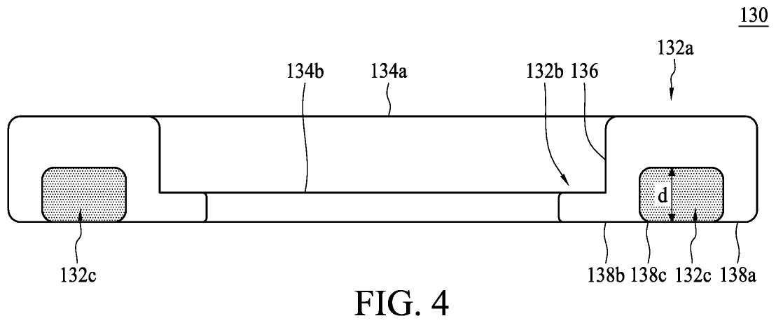

FIG. 4 is an enlarged view of the edge ring 130 according to aspects of one or more embodiments of the present disclosure. In some embodiments, the edge ring 130 further includes a third portion 132c received in the recess. In such embodiments, the third portion 132c has a third bottom surface 138c. The third bottom surface 138c is aligned with and coupled to the first bottom surface 138a, as shown in FIG. 4. Further, the first bottom surface 138a, the second bottom surface 138b and the third bottom surface 138c are in contact with the ring assembly 128 or the pedestal 106. In some embodiments, at least the second bottom surface 138b is in contact with the pedestal 106. In some embodiments, a width of the third portion 132c is less than the width of the first portion 132a, and a thickness of the third portion 132c is less than the thickness of the first portion 132a. Further, the dielectric constant of the third portion 132c is less than the dielectric constant of the first portion 132a and the second portion 132b. For example, the third portion 132c can include air matter, silicon carbide or yttrium material, and the like.

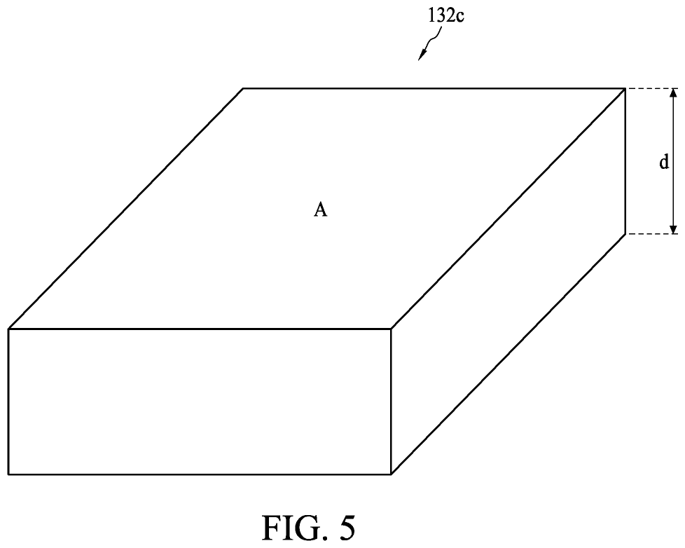

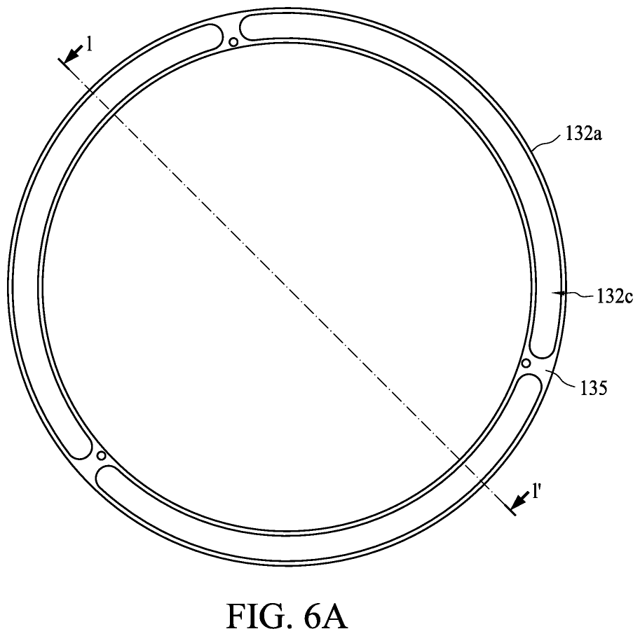

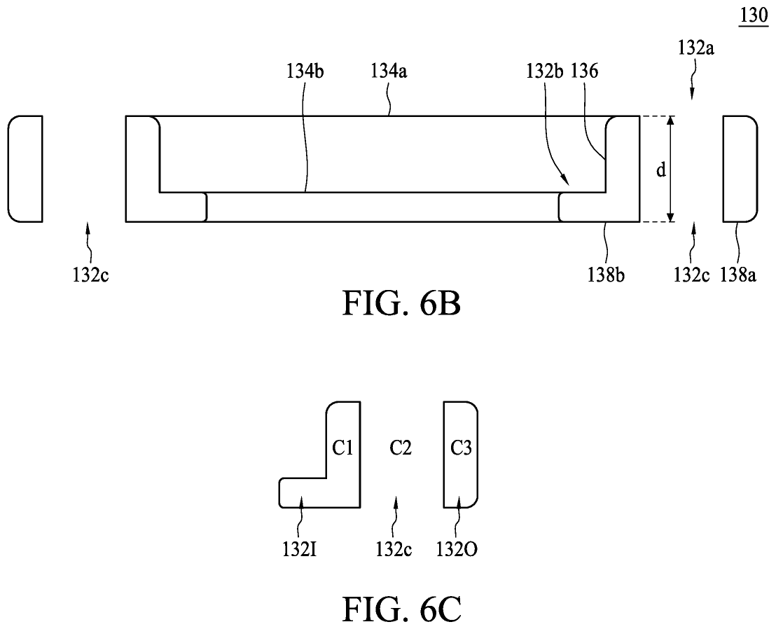

FIG. 5 is an enlarged view of the third portion of the edge ring according to aspects of one or more embodiments of the present disclosure. It should be noted that, although only the third portion 132c is illustrated in FIG. 6, those skilled in the art can easily understand the spatial relationship between the first portion 132a, the second portion 132b and the third portion 132c according to the aforementioned description. It is understood that an erosion rate of the edge ring 130 is correlated to an electric potential of the edge ring 130, and the electric potential of the edge ring 130 is directly proportional to a capacitance of the edge ring 130. Further, the capacitance of the edge ring 130 is correlated to the dielectric constant of the third portion 132c, an area A of the third portion 132c and the thickness d of the third portion 132c, as shown in formula (1):

$$C = {∈}_{0} {∈}_{r} \frac{A}{d} \qquad ( 1 )$$

In some embodiments, when the first portion 132a and the second portion 132b are made of silicon carbide, silicon or quartz, the third portion 132c can include materials having a dielectric constant less than that of the first portion 132a and the second portion 132b. For example, the third portion 132c can be a hollowed portion sealed by the first portion 132a and the seal member 137, wherein the dielectric constant of the third portion 132c is approximately 1. In some embodiments, by adjusting the area A and/or the thickness d of the third portion 132c, the capacitance can be adjusted to any desired value. In some embodiments, by adjusting the area A and/or the thickness d, the capacitance of the edge ring 130 including the first, second and third portions 132a, 132b and 132c is caused to be less than the capacitance of an edge ring without the third portion. In some embodiments, by adjusting the area A and/or the thickness d, the capacitance of the first portion 132a of the edge ring 130 is caused to be less than the capacitance of an edge ring without the third portion.

Referring to FIGS. 6A, 6B and 6C, FIG. 6A is a top view of an edge ring 130 according to aspects of one or more embodiments of the present disclosure, FIG. 6B is a cross-sectional view taken along line I-I′ of FIG. 6A, and FIG. 6C illustrates a portion of the edge ring shown in FIG. 6A. In some embodiments, the recess 132c extends from the first top surface 134a of the first portion 132a to a bottom surface 138a of the first portion 132a such that the first portion 132a has a frame-like configuration, as shown in FIG. 6A. In some embodiments, the recess 132c may divide the edge ring 130 into an outer portion 132O and an inner portion 132I, as shown in FIG. 6C. In some embodiments, the edge ring 130 further includes an alignment anchor 135 within the recess 132c, as shown in FIG. 6A. The alignment anchor 135 helps to position the edge ring 130 on the ring assembly 128 or the pedestal 106. Additionally, the alignment anchor 135 couples the outer portion 132O and the inner portion 132I.

As mentioned above, an erosion rate of the edge ring 130 is correlated to an electric potential of the edge ring 130, and the electric potential of the edge ring 130 is directly proportional to a capacitance of the edge ring 130. Further, the capacitance of the edge ring 130 is correlated to a capacitance C1 of the inner portion 132I, a capacitance C2 of the recess 132c and a capacitance C3 of the outer portion 132O, as shown in formula (2):

C=C1+C2+C3 (2)

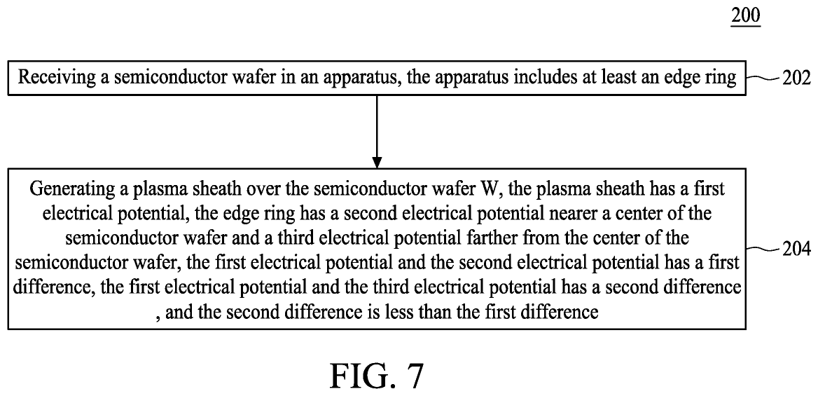

FIG. 7 is a flowchart representing a method for treating a semiconductor wafer according to aspects of the present disclosure. In some embodiments, the treatment includes an etching operation. The method for treating the semiconductor wafer 200 includes an operation 202, receiving a semiconductor wafer W in an apparatus. The apparatus for etching can include the apparatus for etching 100 as mentioned above. For example, the apparatus for etching 100 can include the chamber 102 defined by the chamber housing 104, the pedestal 106, the vacuum pump 108 controlled by a controller 110, a first electrode 112 electrically biased by a lower RF generator 116 controlled by the controller 110, a second electrode 114 electrically biased by an upper RF generator 118 controlled by the controller 110, an etchant delivery system 126 coupled to a etchant controller 124, a manifold 122 and a showerhead 120, a ring assembly 128 surrounding the pedestal 106 and an edge ring 130. The method for treating the semiconductor wafer 200 further includes an operation 204, generating a plasma sheath over the semiconductor wafer W. It should be noted that in some embodiments, during the operation 204, the plasma sheath has a first electric potential, the edge ring has a second electric potential near a center of the semiconductor wafer and a third electric potential away from the center of the semiconductor wafer, the first electric potential and the second electric potential have a first difference, the first electric potential and the third electric potential have a second difference, and the second difference is less than the first difference.

Referring to FIGS. 1, 7 and 8, in some embodiments, a semiconductor wafer W is received in the apparatus for etching 100 in operation 202. The semiconductor wafer W is placed onto the pedestal 106. In some embodiments, the placement of the semiconductor wafer W can be guided at least partly through the use of the ring set 128 in order to align the semiconductor wafer W with the pedestal 106. After the placing of the semiconductor wafer, an attachment operation can be performed to hold the semiconductor wafer W.

In some embodiments, the treating, such as an etching operation, can be initiated by the controller 110. Accordingly, one or more etchant gases and carrier gases are provided into the chamber 102 through the etchant delivery system 126, the etchant controller 124, the manifold 122 and the showerhead 120. In some embodiments, a plasma can be ignited, the lower electrode 112 is biased by the lower RF generator 116 to apply a power, and the upper electrode 114 is biased by the upper RF generator 118 to apply a power.

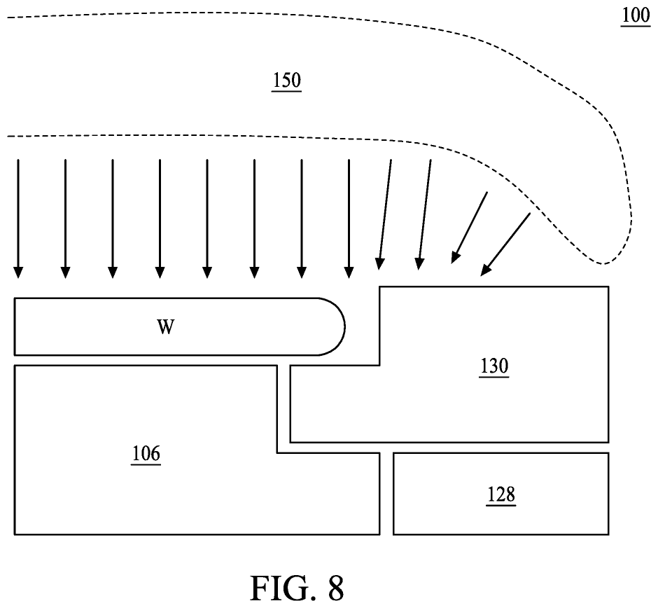

As shown in FIG. 8, an electrical field and a plasma sheath (represented in FIG. 8 by the dashed lines labeled 150) are created over the surface of the semiconductor wafer W in operation 204. The electrical field and the plasma sheath 150 help to move and accelerate ions from the plasma toward the surface of the semiconductor wafer W, as shown by arrows in FIG. 8.

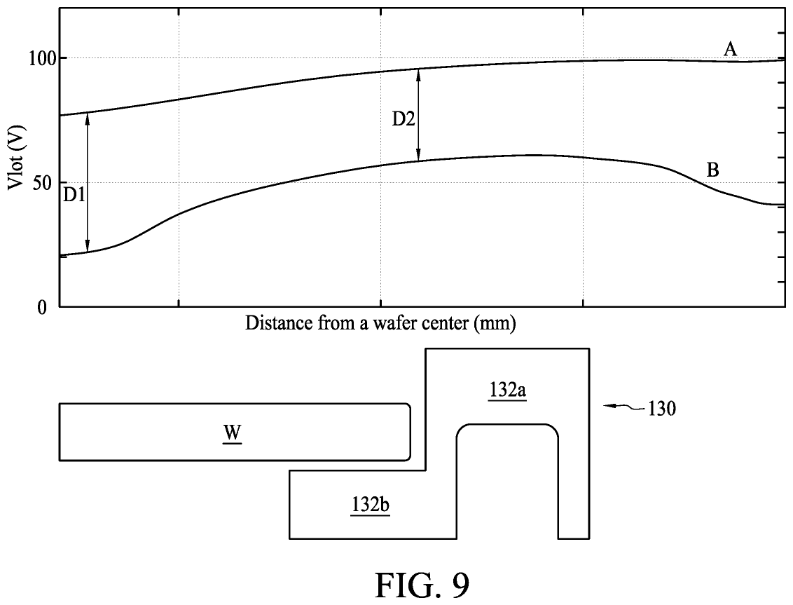

Please refer to FIGS. 8 and 9. The plasma sheath 150 shown in FIG. 8 has an electric potential during the etching operation, and the electric potential of the plasma sheath 150 can be measured and depicted as shown by line A in FIG. 9. In some embodiments, the electric potential of the plasma sheath 150 can be measured from a point above a wafer center to a point above a wafer edge. In some embodiments, the electric potential of the plasma sheath 150 can be measured from a point above the edge ring 130 outside of the area above the semiconductor wafer W, as shown in FIG. 9.

The edge ring 130 has an electric potential during the etching operation, and the electric potential of the edge ring 130 can be measured and depicted as shown by line B in FIG. 9. In some embodiments, the electric potential of the edge ring 130 can be measured from a point above a wafer center to a pint above a wafer edge. In some embodiments, the electric potentials of the edge ring 130 can be measured from an edge of the first portion 132a outside of the area above the semiconductor wafer W, as shown in FIG. 9. In some embodiments, an electric potential of the edge ring 130 nearest to the wafer center may be substantially equal to an electric potential of the semiconductor wafer W during the etching operation. As shown in FIG. 9, the electric potentials of the edge ring 130 may be increased from the second portion 132b to the first portion 132a.

Still referring to FIG. 9, in some embodiments, the electric potential of the sheath 150 near the wafer center and the electric potential of the edge ring 130 near the wafer center have a first difference D1. The electric potential of the plasma sheath 150 away from the wafer center and the electric potential of the edge ring 130 away from the wafer center have a second difference D2. For example, the electric potential of the plasma sheath 150 above the first portion 132a of the edge ring 130 and the electric potential of the first portion 132a of the edge ring 130 away from the wafer center have the second difference D2. In some embodiments, the second difference D2 is less than the first difference D1, as shown in FIG. 9. In some embodiments, the second difference D2 is less than the first difference D1. In some embodiments, a difference can be defined between the first difference D1 and the second difference D2, and the difference can be between approximately 30% of the first difference D1 and approximately 50% of the first difference D1.

It should be understood that an etching rate of the etching operation on the surface of the semiconductor wafer W is directly proportional to the difference between the electric potential of the plasma sheath 150 and the electric potential of the semiconductor wafer W. In some embodiments, by adjusting the electric potential of the semiconductor wafer W, charged species in the plasma can be directed to impinge upon the surface of the semiconductor wafer W and thereby remove material (e.g., atoms) therefrom. Similarly, an etching rate of the etching operation on the surface of the edge ring 130, also referred to as an erosion rate of the edge ring 130 is directly proportional to the difference between the electric potential of the plasma sheath 150 and the electric potential of the edge ring 130.

As mentioned above, the electric potential of the edge ring 130 at a point near the wafer center may be substantially equal to an electric potential of the semiconductor wafer W during the etching operation. Therefore, the first difference D1 may be similar to a difference between the electric potential of the plasma sheath 150 and the electric potential of the semiconductor wafer W. In other words, impact to the etching rate on the surface of the semiconductor wafer W from the edge ring 130 is less during the etching operation.

In some embodiments, the second difference D2 is less than the first difference D1, and therefore the erosion rate is reduced. In some embodiments, it is found that the second difference D2 may be great enough to cause the reduction of the erosion rate near the first portion 132a, where the edge ring 130 is not covered by the semiconductor wafer W. It is therefore observed that the erosion rate can be reduced with less influence on the etching rate of the etching operation on the surface of the semiconductor wafer W.

In some embodiments, the second difference D2 can be adjusted by adjusting the electric potential of the first portion 132a of the edge ring 130, and the electric potential of the first portion 132a can be adjusted by adjusting the capacitance of the first portion 132a. For example, by increasing the capacitance of the first portion 132a, the electric potential of the first portion 132a is increased, and the second difference D2 is reduced. As mentioned above, the second difference D2 can be less than the first difference D1. Consequently, the erosion rate of the first portion 132a, which is not covered by the semiconductor wafer W, is reduced.

As mentioned above, the capacitance of the first portion 132a of the edge ring 130 can be adjusted by selecting a low-k dielectric material and/or by adjusting an area and/or a thickness of the third portion 132c of the edge ring 130. In other words, by selecting the low-k dielectric material and/or by adjusting the area and/or the thickness of the third portion 132c of the edge ring 130, the erosion rate can be reduced.

As mentioned above, the second difference D2 is less than the first difference D1, and the difference between the first difference D1 and the second difference D2 is between approximate 30% of the first difference D1 and approximately 50% of the first difference D1. In some comparative approaches, when the difference between the first difference D1 and the second difference D2 is less than approximately 30% of the first difference D1, the erosion rate of the first portion 132a cannot be reduced. Consequently, the etching rate may be impacted hence process performance may be unpredictable. Further, because the erosion rate cannot be reduced, the service life of the edge ring is reduced. In some alternative approaches, when the difference between the first difference D1 and the second difference D2 is greater than approximately 50% of the first difference D1, the etching rate of the etching operation on the surface of the semiconductor wafer W is adversely impacted.

The present disclosure therefore provides an edge ring and an apparatus including the edge ring that includes an inner body with low dielectric constant (low-k) materials. In some embodiments, the inner body with the low-k material helps to reduce capacitance of the edge ring, resulting in a capacitance that is inversely proportional to the erosion rate. Accordingly, the etching rate may be maintained and the process performance may remain predictable. Further, since the erosion rate is reduced, the service life of the edge ring is increased.

In some embodiments, an edge ring for etching apparatus is provided. The edge ring includes a first portion having a first top surface, a second portion coupled to the first portion and having a second top surface lower the first top surface, and a recess defined in the first portion.

In some embodiments, the first portion has inner surfaces exposed through the recess. In some embodiments, the recess extends from the first top surface of the first portion to a bottom surface of the first portion such that the first portion has a frame-like configuration.

In some embodiments, the edge ring further includes a third portion received within the recess. In some embodiments, the first portion and the second portion have a first dielectric constant, and the third portion has a second dielectric constant. In some embodiments, the first dielectric constant is greater than the second dielectric constant.

In some embodiments, the first portion includes a seal member sealing the recess. In some embodiments, the recess includes air sealed within the recess and seal member. In some embodiments, the recess is sealed at a vacuum pressure.

In some embodiments, an apparatus for etching is provided. The apparatus includes a chamber, a pedestal configured to receive and support a semiconductor wafer in the chamber, and an edge ring disposed over the pedestal. In some embodiments, the edge ring includes a first portion have a first top surface, a second portion coupled to the first portion and having a second top surface lower than the first top surface, and an recess defined in the first portion. In some embodiments, the second top surface is under the semiconductor wafer. In some embodiments, the recess has a depth, and a distance between the pedestal and an inner surface of the recess is substantially equal to the depth of the recess.

In some embodiments, the edge ring further includes a third portion received in the recess. In some embodiments, the first portion and the second portion have a first dielectric constant, and the third portion has a second dielectric constant. In some embodiments, the second dielectric constant is less than the first dielectric constant. In some embodiments, the edge ring further includes an alignment anchor. In some embodiments, the first portion has a bottom surface opposite to the first top surface, the second portion has a second bottom surface opposite to the second top surface and coupled to the first bottom surface, and the third portion has a third bottom surface aligned with the first bottom surface and the second bottom surface. In some embodiments, at least the second bottom surface is in contact with the pedestal.

In some embodiments, a method for treating a semiconductor device is provided. The method includes the following operations. A semiconductor wafer is received in an apparatus. A plasma sheath is generated over the semiconductor wafer. In some embodiments, the apparatus includes a chamber, a pedestal configured to support the semiconductor wafer, a first electrode and a second electrode configured to apply RF power, and an edge ring over an edge of the pedestal. In some embodiments, the edge ring includes a first portion having a first top surface, a second portion coupled to the first portion and having second top surface lower than the first top surface, and a third portion disposed within the first portion. In some embodiments, the first portion and the second portion have a first dielectric constant, and the third portion has a second dielectric constant. In some embodiments, the plasma sheath has a first electric potential, the edge ring has a second electric potential near a center of the semiconductor wafer and a third electric potential away from the center of the semiconductor wafer, the first electric potential and the second electric potential have a first difference, the first electric potential and the third electric potential have a second difference, and the second difference is less than the first difference.

In some embodiments, the second difference is less than the first difference. In some embodiments, a difference is between the first difference and the second difference, and the difference is between approximately 30% of the first difference D1 and approximately 50% of the first difference.

In some embodiments, the first portion and the second portion include silicon or quartz.

In some embodiments, the third portion includes air at an atmosphere pressure. In some embodiments, the third portion is at a vacuum pressure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An edge ring for an etching apparatus, comprising:
a first portion having a first top surface;
a second portion coupled to the first portion and having a second top surface lower than the first top surface; and
a recess defined in the first portion,
wherein the recess has a surface substantially parallel to the first top surface of the first portion and exposed through an opening of the recess, a depth of the recess is measured from the opening of the recess to the surface of the recess, and the depth of the recess is less than a thickness of the first portion.

2-8. (canceled)

9. An apparatus for etching, comprising:
a chamber;
a pedestal configured to receive and support a semiconductor wafer in the chamber; and
an edge ring disposed over the pedestal, wherein the edge ring comprises:
a first portion having a first top surface;
a second portion coupled to the first portion and having a second top surface lower than the first top surface, wherein the second top surface is under the semiconductor wafer; and
a recess defined in the first portion,
wherein the recess has a surface substantially parallel to the first top surface of the first portion and exposed through an opening of the recess, a depth of the recess is measured from the opening of the recess to the surface of the recess, and the depth of the recess is less than a thickness of the first portion.

10-11. (canceled)

12. The apparatus of claim 9, wherein the edge ring further comprises an alignment anchor.

13. The apparatus of claim 9, wherein the first portion has a first bottom surface opposite to the first top surface, the second portion has a second bottom surface opposite to the second top surface and coupled to the first bottom surface, and at least the second bottom surface is in contact with the pedestal.

14. The apparatus of claim 9, wherein a distance between the pedestal and an inner surface of the recess is substantially equal to the depth of the recess.

15-20. (canceled)

21. An apparatus for an etching apparatus, comprising:
a ring assembly; and
an edge ring disposed over the ring assembly, wherein the edge ring comprises:
a first portion having a first top surface;
a second portion coupled to the first portion and having a second top surface lower than the first top surface;
a recess defined in the first portion; and
a seal member sealing the recess,
wherein the recess is sealed to have a vacuum pressure.

22. The apparatus of claim 21, wherein the ring assembly comprises an annular configuration configured to receive the edge ring.

23. The apparatus of claim 21, wherein a depth of the recess is less than a thickness of the first portion.

24-26. (canceled)

27. The edge ring of claim 1, further comprising an alignment anchor.

28. The edge ring of claim 1, wherein the first portion has a first bottom surface opposite to the first top surface, the second portion has a second bottom surface opposite to the second top surface, and the first bottom surface is aligned with the second bottom surface.

29. The edge ring of claim 28, wherein at least the second bottom surface are in contact with a pedestal.

30. The edge ring of claim 29, wherein the depth of the recess is substantially equal to a distance between the pedestal and a sidewall of the recess.

31. The edge ring of claim 1, wherein a width of the first portion is greater than a width of the second portion.

32. The apparatus of claim 9, wherein a width of the first portion of the edge ring is greater than a width of second portion of the edge ring.

33. The apparatus of claim 21, wherein the edge ring further comprises an alignment anchor.

34. The apparatus of claim 21, wherein the first portion has a first bottom surface opposite to the first top surface, the second portion has a second bottom surface opposite to the second top surface, and the first bottom surface is aligned with the second bottom surface.

35. The apparatus of claim 34, wherein the seal member is coupled to the first bottom surface and the second bottom surface.

36. The apparatus of claim 34, wherein the first bottom surface, the second bottom surface and the seal member are in contact with the ring assembly.

37. The apparatus of claim 34, wherein the first bottom surface, the second bottom surface and the seal member are in contact with a pedestal.

38. The apparatus of claim 34, wherein the recess has a depth, and a distance between the pedestal and an inner surface of the recess is substantially equal to a depth of the recess.
